(19) United States
(12) Patent Application Publication
(10) Pub. No.: US 2011/0012664 A1
(43) Pub. Date: Jan. 20, 2011

(54) CLOCK SIGNAL AMPLIFIER CIRCUIT

(75) Inventors: Masayoshi KINOSHITA, Osaka (JP); Kazuaki Sogawa, Osaka (JP); Yuji Yamada, Osaka (JP)

Correspondence Address: McDERMOTT WILL & EMERY LLP, 600 13st Street, N.W., Washington, DC, 20005-3096, US

(73) Assignee: PANASONIC CORPORATION, Osaka (JP)

(21) Appl. No.: 12/892,542

(22) Filed: Sep. 28, 2010

Related U.S. Application Data
(63) Continuation of application No. PCT/JP2009/001092, filed on Mar. 11, 2009.

(30) Foreign Application Priority Data
Jun. 2, 2008 (JP) 2008-144875

(51) Int. Cl. H03L 5/00

(52) U.S. Cl. 327/306

(57) ABSTRACT

A clock signal amplifier circuit includes: an inverter; a coupling capacitor connected to the input of the inverter; two resistors connected in series between the power supply potential and the ground potential, a connection node of the two resistors being connected to the input of the inverter; a feedback resistor provided between the input and output of the inverter; and two switches configured to perform a same open/close operation according to a control signal, the two switches being provided on any two of a supply path of the power supply potential to the inverter, a supply path of the ground potential to the inverter, and a feedback path of the inverter via the feedback resistor.

### CROSS-REFERENCE TO RELATED APPLICATION

This is a continuation of PCT International Application PCT/JP2009/001092 filed on Mar. 11, 2009, which claims priority to Japanese Patent Application No. 2008-144875 filed on Jun. 2, 2008. The disclosures of these applications including the specifications, the drawings, and the claims are hereby incorporated by reference in their entirety.

### BACKGROUND

The present disclosure relates to a clock signal amplifier circuit that amplifies an input small-amplitude clock signal to a voltage large enough to be usable in digital circuits.

In semiconductor integrated circuits, a clock signal is necessary for computing digital circuits. In general, a clock signal is generated by a quartz oscillator or a clock generation IC placed outside a semiconductor integrated circuit and then input into the semiconductor integrated circuit in many cases. When the amplitude of the clock signal input into the semiconductor integrated circuit is the same as the power supply amplitude of the semiconductor integrated circuit, the input clock signal can be used as it is. However, if the former is smaller than the latter, the clock signal may possibly disappear without being taken into the semiconductor integrated circuit. For this reason, a clock signal amplifier circuit is required for amplifying a small-amplitude clock signal up to the level of the power supply amplitude of the semiconductor integrated circuit.

A typical clock signal amplifier circuit is constructed of an inverter, a coupling capacitor connected to the input side of the inverter, and a feedback resistor connected between the input/output of the inverter. The coupling capacitor removes the DC component of an input clock signal to allow only the AC component thereof to propagate to the inverter at a subsequent stage. The feedback resistor feeds the average DC voltage of the output signal of the inverter back to the input of the inverter. The inverter receives a signal determined by the AC component of the clock signal propagating from the coupling capacitor and the average DC voltage of the inverter output fed from the feedback resistor. In this way, the input small-amplitude clock signal can be amplified.

The typical clock signal amplifier circuit has a problem that the rise time is long. More specifically, a comparatively long time is necessary from startup until output of an amplified clock signal. To address this problem, some clock signal amplifier circuit includes a counter circuit, an operational amplifier, an operational amplifier control circuit, and a reference voltage source in addition to the configuration of the typical clock signal amplifier circuit described above. In this clock signal amplifier circuit, the DC voltage from the operational amplifier is forcefully input into the inverter for a fixed time period counted by the counter circuit after start of operation, thereby to achieve high-speed startup.

### SUMMARY

Although high-speed startup can be achieved, the conventional clock signal amplifier circuit described above, having a number of additional circuits, inevitably increases the development cost and the production cost. Moreover, when no clock signal is being input and when output of an amplified clock signal is unnecessary, the input of the inverter is at midpoint potential, allowing a through current to flow through the inverter and thus wasting power. An illustrative clock signal amplifier circuit can reduce power consumption during halt, as well as achieving high-speed startup, without significant increase in circuit scale.

An illustrative clock signal amplifier circuit, configured to amplify an input clock signal, includes: an inverter; a coupling capacitor connected to an input of the inverter; two resistors connected in series between a power supply potential and a ground potential, a connection node of the two resistors being connected to the input of the inverter; a feedback resistor provided between the input and output of the inverter; and two switches configured to perform a same open/close operation according to a control signal, the two switches being provided on any two of a supply path of the power supply potential to the inverter, a supply path of the ground potential to the inverter, and a feedback path of the inverter via the feedback resistor.

With the above configuration, when the two switches are off, the inverter is halted because no through current flows through the inverter. Also, the feedback path of the inverter is at high impedance, allowing the input of the inverter to be charged with the midpoint potential supplied from the connection node of the two resistors. Thereafter, once the two switches turn on, the inverter starts its operation. At this time, since the input of the inverter has already been close to the logic threshold potential, the inverter can output a large-amplitude clock signal immediately in response to slight AC level fluctuations input via the coupling capacitor.

Another illustrative clock signal amplifier circuit, configured to amplify an input clock signal, includes: a logic circuit configured to output NOR or NAND of first and second inputs; a coupling capacitor connected to the first input of the logic circuit; two resistors connected in series between a power supply potential and a ground potential, a connection node of the two resistors being connected to the first input of the logic circuit; a feedback resistor provided between an output of the logic circuit and the first input of the logic circuit; and a switch configured to perform open/close operation according to the second input of the logic circuit as a control signal, the switch being provided on a feedback path to the first input of the logic circuit via the feedback resistor.

With the above configuration, when the switch is off, the logic circuit is halted because no through current flows through the logic circuit. Also, the feedback path to the first input of the logic circuit is at high impedance, allowing the first input to be charged with the midpoint potential supplied from the connection node of the two resistors. Thereafter, once the switch turns on, the logic circuit starts its operation. At this time, since the first input of the logic circuit has already been close to the logic threshold potential, the logic circuit can output a large-amplitude clock signal immediately in response to slight AC level fluctuations input via the coupling capacitor.

It is preferable that the clock signal amplifier circuit further includes a resistor circuit connected in parallel with the feedback resistor, a resistance value of the resistor circuit increasing with a predetermined time constant after turn-on of the switch. Specifically, the resistor circuit may include: an integrator circuit configured to integrate the control signal; and a transistor connected in parallel with the feedback resistor, an output of the integrator circuit being applied to a gate of the transistor.

With the above configuration, since the impedance of the feedback path of the inverter or the feedback path to the first input of the logic circuit is lower for a time immediately after turn-on of the switch than in normal times, the DC voltage propagation capability from the output of the inverter or the logic circuit to the input thereof is high. Therefore, the inverter or the logic circuit can output a large-amplitude clock signal more speedily in response to slight AC level fluctuations input via the coupling capacitor.

Preferably, the two resistors are transistors of opposite polarities to each other, a gate and source of each of the transistors being connected to each other, or transistors of opposite polarities to each other, a gate and drain of each of the transistors being connected to each other.

With the above configuration, when the logic threshold potential of the inverter or the logic circuit deviates from an ideal value due to fabrication variations in the CMOS process, the potential at the connection node of the two resistors also deviates. Therefore, the input of the inverter or the first input of the logic circuit can be charged with the actual logic threshold potential, permitting further speedup of startup of the clock signal amplifier circuit.

### BRIEF DESCRIPTION OF THE DRAWINGS

FIG. 1 shows a configuration of a clock signal amplifier circuit of the first embodiment.

FIG. 2 is a specific circuit diagram of the clock signal amplifier circuit of FIG. 1.

FIG. 3 is an operational waveform chart of the clock signal amplifier circuit of the first embodiment.

FIG. 4 shows a configuration of a clock signal amplifier circuit of a variation of the first embodiment.

FIG. 5 shows a configuration of a clock signal amplifier circuit of another variation of the first embodiment.

FIG. 6 shows a configuration of a clock signal amplifier circuit of the second embodiment.

FIG. 7 is a specific circuit diagram of the clock signal amplifier circuit of FIG. 6.

FIG. 8 shows a configuration of a clock signal amplifier circuit of a variation of the second embodiment.

FIG. 9 shows a configuration of a clock signal amplifier circuit of the third embodiment.

### DETAILED DESCRIPTION

Preferred embodiments of the present invention will be described hereinafter with reference to the accompanying drawings.

### First Embodiment

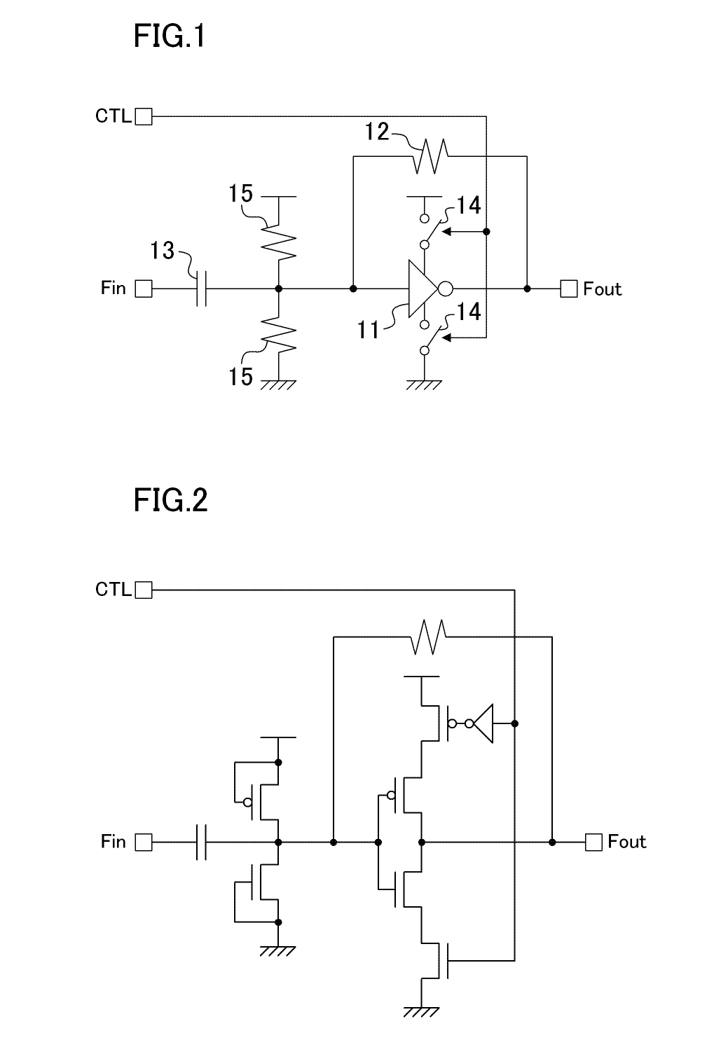

FIG. 1 shows a configuration of a clock signal amplifier circuit of the first embodiment. In the clock signal amplifier circuit of this embodiment, a feedback resistor 12 is connected between the input and output of an inverter 11. The inverter 11 amplifies the AC component of a small-amplitude clock signal Fin input via a coupling capacitor 13 and outputs a clock signal Fout.

Switches 14 are respectively provided on supply paths of the power supply potential and the ground potential to the inverter 11. These switches 14 perform the same open/close operation according to a control signal CTL. For example, the switches 14 are conducting when the control signal CTL is high, and are not conducting when the control signal CTL is low.

As the control signal CTL, a hardware reset signal for the entire system including the clock signal amplifier circuit can be used. In other words, the clock signal amplifier circuit can be controlled so that it is halted when the entire system is being reset and operated after the reset is cancelled.

To the input of the inverter 11, connected is a connection node of two resistors 15 that are connected in series between the power supply potential and the ground potential. The two resistors 15 are provided to apply a midpoint potential between the power supply potential and the ground potential to the input of the inverter, as will be described later. It is therefore preferable that both have a resistance value as high as several MΩ.

FIG. 2 shows a specific circuit configuration of the clock signal amplifier circuit of FIG. 1, in which the reference characters are omitted. As shown in FIG. 2, the two resistors 15 can be realized with a p-type transistor and an n-type transistor in each of which the gate and the source are connected to each other. In the thus-connected transistors, a leakage current flows between the drain and the source. With this leakage current, the input of the inverter 11 can be at the midpoint potential.

A p-type transistor and an n-type transistor constituting the inverter 11 are normally designed to have the same dive capability. Therefore, the inverter 11 performs logic inversion with a potential just at the midpoint between the power supply potential and the ground potential (VDD/2) as a logic threshold potential. However, if the balance of the drive capability between the p-type transistor and the n-type transistor is lost due to fabrication variations in the CMOS process and the like, the logic threshold potential of the inverter 11 will be deviated from VDD/2. Incidentally, if the two resistors 15 are realized with resistor elements having the same resistance value, the exact potential VDD/2 will be supplied at the connection node of these resistors 15 irrespective of fabrication variations, and thus the input of the inverter 11 cannot be charged with the actual logic threshold potential. On the contrary, when the two resistors 15 are realized with a p-type transistor and an n-type transistor as is the inverter 11, the potential at the connection node of the resistors 15 will also be deviated according to a deviation in the logic threshold potential of the inverter 11 due to fabrication variations, if any, and thus the input of the inverter 11 can be charged with the actual logic threshold potential.

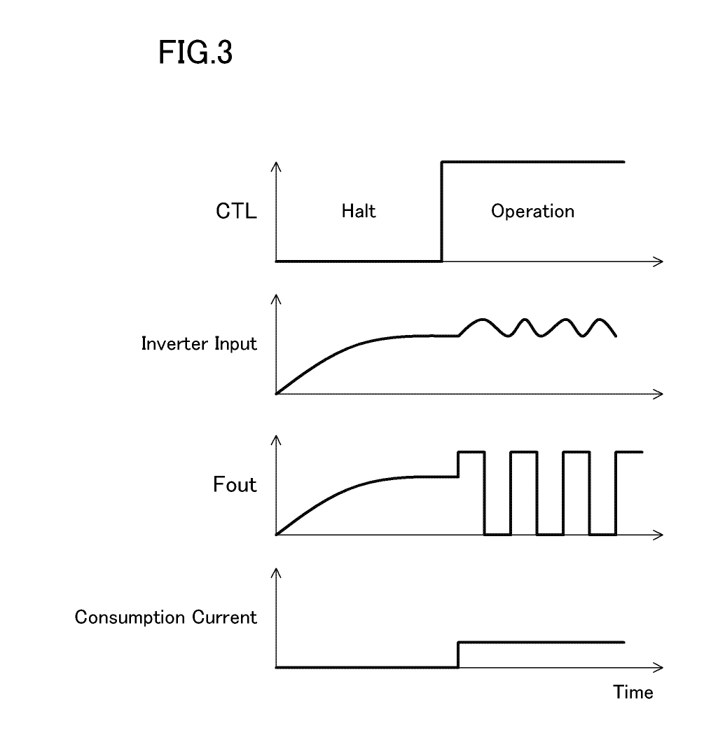

The operation of the clock signal amplifier circuit of this embodiment will be described with reference to the operational waveform chart of FIG. 3. When the clock signal amplifier circuit is halted, that is, when the control signal CTL is not active, the two switches 14 are not conducting. This isolates the inverter 11 from both the power supply potential and the ground potential, and thus the output of the inverter 11 is at high impedance. Therefore, with no feedback of the output of the inverter 11 to the input thereof via the feedback resistor 12, the input of the inverter 11 is gradually charged with the potential at the connection node of the two resistors 15 and stabilized at the midpoint potential. Although the input of the inverter 11 is at the midpoint potential, no through current flows through the inverter 11 because the two switches 14 are off. Therefore, during halt of the clock signal amplifier circuit, only a small amount of current flowing through the two resistors 15 is consumed.

Once the control signal CTL turns active, the two switches 14 become conducting. This connects the inverter 11 to the power supply potential and the ground potential, allowing start of operation. At this time, the input of the inverter 11 has already been charged to a level close to the operable logic threshold potential. Therefore, the inverter 11 can output the clock signal Fout upon receipt of the AC component of the small-amplitude clock signal Fin via the coupling capacitor 13. In particular, having the two resistors 15 realized with transistors, even if the logic threshold potential of the inverter 11 is deviated from VDD/2 due to fabrication variations, the input of the inverter 11 can be charged with the actual logic threshold potential. Therefore, the inverter 11 can output the clock signal Fout immediately after receipt of the AC component of the clock signal Fin.

As described above, in this embodiment, startup of the clock signal amplifier circuit can be speeded up, and yet the current consumption during halt can be widely reduced. In addition, since the clock signal amplifier circuit of this embodiment can be constructed by only adding the two switches 14 and the two resistors 15 to the typical clock signal amplifier circuit, increase in development cost and fabrication cost can be reduced.

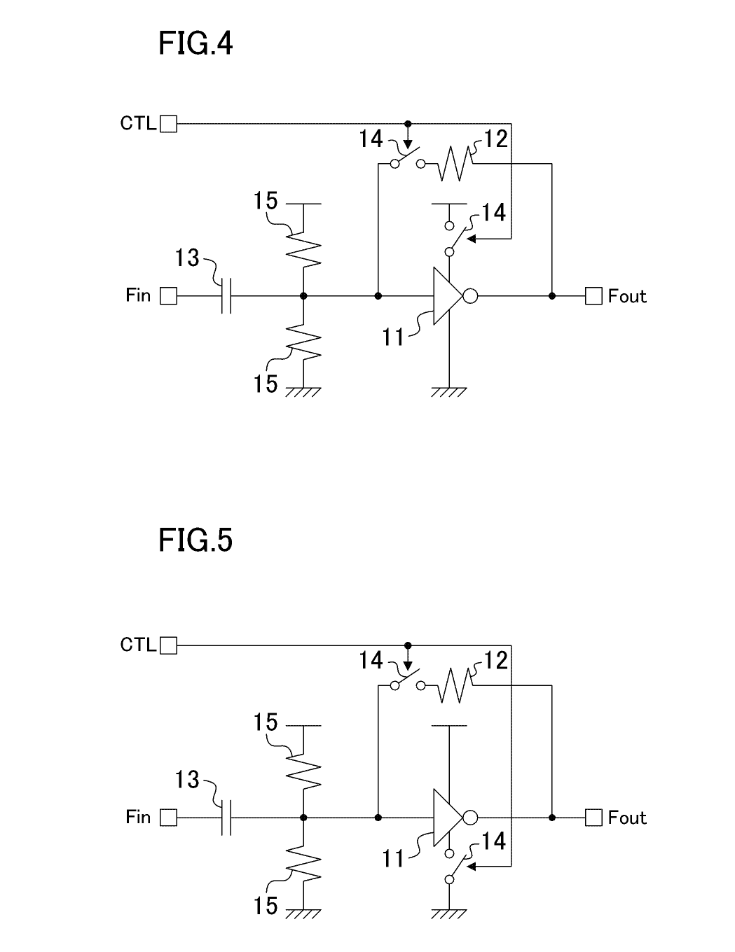

One of the switches 14 may not be provided, and instead a switch 14 may be provided on the feedback path from the output of the inverter 11 to the input thereof via the feedback resistor 12. FIGS. 4 and 5 show variations of the clock signal amplifier circuit of FIG. 1. In these variations, although the positions of insertion of the two switches 14 are different, the current consumption of the inverter 11 can be reduced, and the output feedback path of the inverter 11 can be at high impedance, during halt of the clock signal amplifier circuit. Therefore, effects similar to those described above can be obtained.

### Second Embodiment

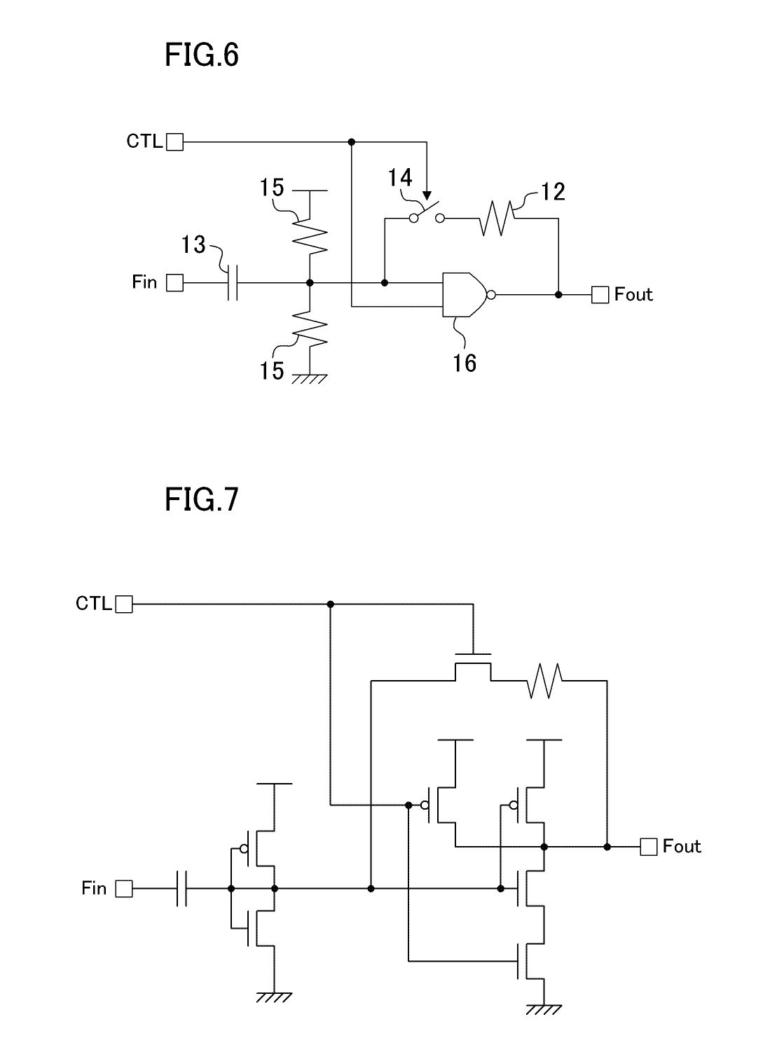

FIG. 6 shows a configuration of a clock signal amplifier circuit of the second embodiment. In the clock signal amplifier circuit of this embodiment, a feedback resistor 12 and a switch 14 are connected between the output and one input of a 2-input NAND element 16. The switch 14 performs open/close operation according to a high-active control signal CTL. In other words, the switch 14 is conducting when the control signal CTL is high, and not conducting when the control signal CTL is low. The control signal CTL is also input into the other input of the NAND element 16. The NAND element 16 amplifies the AC component of a small-amplitude clock signal Fin input via a coupling capacitor 13 and outputs a clock signal Fout. The coupling capacitor 13 and two resistors 15 are the same as those described above.

FIG. 7 shows a specific circuit configuration of the clock signal amplifier circuit of FIG. 6, in which the reference characters are omitted. As shown in FIG. 7, the two resistors 15 can be realized with a p-type transistor and an n-type transistor in each of which the gate and the drain are connected to each other. In the thus-connected transistors, although a larger amount of drain current flows than when the gate and the source are connected to each other, the drain current can be reduced by means such as increasing the channel length of the transistor.

The operation of the clock signal amplifier circuit of this embodiment will be described. When the control signal CTL is low, the clock signal amplifier circuit is in its halt state, and the output of the NAND element 16 is high. At this time, since the switch 14 is not conducting, the output feedback path of the NAND element 16 is at high impedance. Therefore, with no feedback of the output of the NAND element 16 to the input thereof via the feedback resistor 12, the input is gradually charged with the potential at the connection node of the two resistors 15 and stabilized at the midpoint potential. Although one input of the NAND element 16 is at the midpoint potential, no through current flows through the NAND element 16 because the switch 14 is off. Therefore, during halt of the clock signal amplifier circuit, only a small amount of current flowing through the two resistors 15 is consumed.

Once the control signal CTL goes high, the NAND element 16 starts to function as an inverter, and also the switch 14 becomes conducting, enabling the output feedback of the NAND element 16. At this time, the input of the NAND element 16 has already been charged to a level close to the logic threshold potential that permits inverter operation. Therefore, the NAND element 16 can output the clock signal Fout upon receipt of the AC component of the small-amplitude clock signal Fin via the coupling capacitor 13.

As described above, in this embodiment, startup of the clock signal amplifier circuit can be speeded up, and yet current consumption during halt can be widely reduced. In addition, since the clock signal amplifier circuit of this embodiment has a very simple configuration, the development cost and the fabrication cost can be reduced.

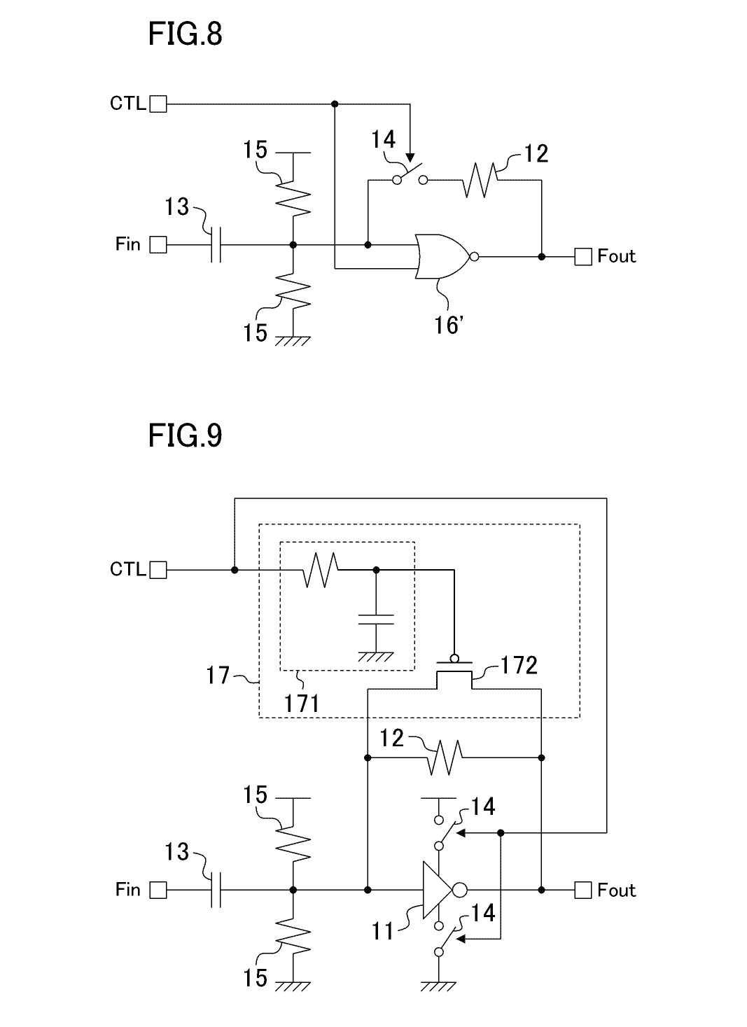

When the control signal CTL is low-active, the NAND element 16 may be replaced with a NOR element. FIG. 8 shows a variation of the clock signal amplifier circuit of FIG. 6. Such a clock signal amplifier circuit using a NOR element 16′ can also obtain effects similar to those described above.

### Third Embodiment

FIG. 9 shows a configuration of a clock signal amplifier circuit of the third embodiment. The clock signal amplifier circuit of this embodiment includes a resistor circuit 17 connected in parallel with the feedback resistor 12 in addition to the configuration of the clock signal amplifier circuit of the first embodiment. Only points different from the first embodiment will be described hereinafter.

The resistor circuit 17 includes: an integrator circuit 171 that integrates the control signal CTL; and a transistor 172 that is connected in parallel with the feedback resistor 12 and to the gate of which the output of the integrator circuit 171 is applied. In other words, in the resistor circuit 17, the resistance value increases with the CR time constant of the integrator circuit 171 after transition of the control signal CTL from low to high. In this embodiment, the transistor 172 is of p-type because the control signal CTL is assumed to be high-active. When the control signal CTL is low-active, the transistor 172 should be of n-type.

The operation of the clock signal amplifier circuit of this embodiment will be described. When the control signal CTL is low, the on resistance of the transistor 172 of the resistor circuit 17 is small. However, since the output of the inverter 11 is at high impedance, it is not fed back to the input of the inverter 11 via the feedback resistor 12 and the resistor circuit 17. Therefore, the input of the inverter 11 is gradually charged with the potential at the connection node of the two resistors 15 and stabilized at the midpoint potential.

Once the control signal CTL goes high, the inverter 11 starts operation. At this time, the input of the inverter 11 has already been charged to a level close to the operable logic threshold potential. Also, since the transistor 172 is still on for a time immediately after transition of the control signal CTL from low to high, the combined resistance of the feedback resistor 12 and the on resistance of the transistor 172 is small. This means that the DC voltage propagation capability from the output of the inverter 11 to the input thereof is high. Therefore, the inverter 11 can output the clock signal Fout upon receipt of the AC component of the small-amplitude clock signal Fin via the coupling capacitor 13.

Thereafter, the resistor circuit 17 gradually increases its resistance value, and becomes high impedance once the transistor 172 turns off. The output of the inverter 11 is now fed back to the input thereof only via the feedback resistor 12, permitting amplification of the small-amplitude clock signal Fin.

As described above, in this embodiment, startup of the clock signal amplifier circuit can be further speeded up. The resistor circuit 17 can also be added to the configuration of the clock signal amplifier circuit of the second embodiment. In this case, also, startup of the clock signal amplifier circuit of the second embodiment can be further speeded up.

What is claimed is:

1. A clock signal amplifier circuit configured to amplify an input clock signal, comprising:
an inverter;
a coupling capacitor connected to an input of the inverter;
two resistors connected in series between a power supply potential and a ground potential, a connection node of the two resistors being connected to the input of the inverter;
a feedback resistor provided between the input and output of the inverter; and
two switches each configured to perform an open/close operation according to a control signal, the two switches being provided on any two of a supply path of the power supply potential to the inverter, a supply path of the ground potential to the inverter, and a feedback path of the inverter via the feedback resistor.

2. The clock signal amplifier circuit of claim 1, further comprising:
a resistor circuit connected in parallel with the feedback resistor, a resistance value of the resistor circuit increasing with a predetermined time constant after turn-on of the switches.

3. The clock signal amplifier circuit of claim 2, wherein
the resistor circuit comprises:
an integrator circuit configured to integrate the control signal; and
a transistor connected in parallel with the feedback resistor, an output of the integrator circuit being applied to a gate of the transistor.

4. The clock signal amplifier circuit of claim 1, wherein
the two resistors are transistors of opposite polarities to each other, a gate and source of each of the transistors being connected to each other.

5. The clock signal amplifier circuit of claim 1, wherein
the two resistors are transistors of opposite polarities to each other, a gate and drain of each of the transistors being connected to each other.

6. A clock signal amplifier circuit configured to amplify an input clock signal, comprising:
a logic circuit configured to output NOR or NAND of first and second inputs;
a coupling capacitor connected to the first input of the logic circuit;
two resistors connected in series between a power supply potential and a ground potential, a connection node of the two resistors being connected to the first input of the logic circuit;
a feedback resistor provided between an output of the logic circuit and the first input of the logic circuit; and
a switch configured to perform open/close operation according to the second input of the logic circuit as a control signal, the switch being provided on a feedback path to the first input of the logic circuit via the feedback resistor.

7. The clock signal amplifier circuit of claim 6, further comprising:
a resistor circuit connected in parallel with the feedback resistor, a resistance value of the resistor circuit increasing with a predetermined time constant after turn-on of the switch.

8. The clock signal amplifier circuit of claim 7, wherein
the resistor circuit comprises:
an integrator circuit configured to integrate the control signal; and
a transistor connected in parallel with the feedback resistor, an output of the integrator circuit being applied to a gate of the transistor.

9. The clock signal amplifier circuit of claim 6, wherein
the two resistors are transistors of opposite polarities to each other, a gate and source of each of the transistors being connected to each other.

10. The clock signal amplifier circuit of claim 6, wherein
the two resistors are transistors of opposite polarities to each other, a gate and drain of each of the transistors being connected to each other.
